(19) United States
(12) Patent Application Publication
(10) Pub. No.: US 2012/0126784 A1
(43) Pub. Date: May 24, 2012

(54) DEVICE FOR MEASURING CURRENT

(75) Inventors: Chun-Guo Liu, Chung-Ho (TW); Ching-Feng Hsieh, Wanhua District (TW)

(73) Assignee: Askey Computer Corporation, Chung-Ho (TW)

(21) Appl. No.: 12/965,472

(22) Filed: Dec. 10, 2010

(30) Foreign Application Priority Data
Nov. 23, 2010 (TW) 99140301

(51) Int. Cl. G01R 19/00

(52) U.S. Cl. 324/103 R

(57) ABSTRACT

A device for measuring current is connected to a data processing apparatus loaded with a current value comparison program for performing a quality test on a portable electronic apparatus with a battery. The portable electronic apparatus has a battery compartment for receiving the battery. The device for measuring current includes: a power supplying module for generating a low-voltage current; a dummy battery with a shape of the battery for inserting into the battery compartment, the dummy battery electrically connected to the power supplying module and the portable electronic apparatus to provide the low-voltage current generated by the power supply module to the portable electronic apparatus, forming a power supply loop to the portable electronic apparatus; and a current measuring module electrically connected to the power supply loop for measuring a current value of the power supply loop when the portable electronic apparatus is performing a specific function and transmitting the measured current value to the data processing apparatus for comparison. The present invention does not heavily rely on manual operations to measure the current of the portable electronic apparatus.

### FIELD OF THE INVENTION

The present invention relates to devices for measuring current, and more particularly, to a device for measuring current of a portable electronic apparatus with a built-in battery.

### BACKGROUND OF THE INVENTION

Generally, manufacturers of electronic devices perform a series of tests on their products before shipping or mass production in order to provide consumers with good-quality products. Among them, one of the tests determines whether current consumptions of a portable electronic apparatus (e.g. a palm computer or smart phone) under different operating conditions are all within their ideal ranges, so as to detect any faulty products at an earlier stage.

Specifically, testing personnel connects a portable electronic apparatus to be tested to an external power supply, and connects a digital multimeter to the power supply. Then, the power supply is operated to provide a low voltage to the portable electronic apparatus, and the portable electronic apparatus is operated to perform a specific built-in function. At this time, the digital multimeter will display a current value consumed by the portable electronic apparatus. The testing personnel then makes a record of it, and determines whether this current value falls within an ideal current range, thereby completes a standard functional test for the portable electronic apparatus.

However, steps involved in such a current testing procedure are complicated and trivial. For example, the digital multimeter, the power supply and the portable electronic apparatus to be tested all have to be connected via probes or connectors. There is a concern that the connectors might fall off during the test. In addition, manual testing and determination are required, thus reducing testing efficiency.

### SUMMARY OF THE INVENTION

In the light of forgoing drawbacks, an objective of the present invention is to provide a device capable of measuring current of a portable electronic apparatus.

Another objective of the present invention is to provide a device for measuring current that allows the testing personnel to obtain a more accurate test result.

In accordance with the above and other objectives, the present invention provides a device for measuring current connected to a data processing apparatus loaded with a current value comparison program for performing a quality test on a portable electronic apparatus with a battery, the portable electronic apparatus having a battery compartment for receiving the battery. The device for measuring current includes: a power supplying module for generating a low-voltage current; a dummy battery with a shape of the battery for inserting into the battery compartment, the dummy battery electrically connected to the power supplying module and the portable electronic apparatus to provide the low-voltage current generated by the power supply module to the portable electronic apparatus, forming a power supply loop to the portable electronic apparatus; and a current measuring module electrically connected to the power supply loop for measuring a current value of the power supply loop when the portable electronic apparatus is performing a specific function and transmitting the measured current value to the data processing apparatus for comparison.

In an implementation aspect of the present invention, the device for measuring current further includes a body including a container on a surface thereof for receiving the portable electronic apparatus.

In an implementation aspect of the present invention, the battery compartment includes a first positive terminal and a first negative terminal corresponding to power output terminals of the battery. The dummy battery includes a second positive terminal and a second negative terminal corresponding to the first positive terminal and the first negative terminal of the battery compartment and with shapes of the power output terminals of the battery. The second positive terminal and the second negative terminal of the dummy battery are connected to the first positive terminal and the first negative terminal of the battery compartment by physical contact, respectively, and connected to the power supplying module via wires.

In an implementation aspect of the present invention, the specific function performed by the portable electronic apparatus includes a call, an incoming call/message notice, wireless network searching, wireless transmission of files, video playing, or message/email inputting. A current range is preset in the current value comparison program, the current range being set correspondingly to the specific function of the portable electronic apparatus, and for comparison with the current value measured by the current measuring module. When the current value falls within the preset current range, the quality of the portable electronic apparatus is considered as good. When the current value falls outside the preset current range, the quality of the portable electronic apparatus is considered as no good.

Therefore, the present invention allows the testing personnel to perform a current measuring procedure on the portable electronic apparatus through simple and convenient steps, which eliminates the shortcoming of the prior art in which a significant amount of manual work is required. Thus, a more accurate test result can be obtained. Further, the overall yield of the portable electronic apparatus is efficiently improved, thus reducing the production cost of the manufacturer is reduced.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram depicting the appearance of a device for measuring current according to an embodiment of the present invention; and

FIG. 2 is a block diagram depicting basic functional architecture of the device for measuring current according to an embodiment of the present invention.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

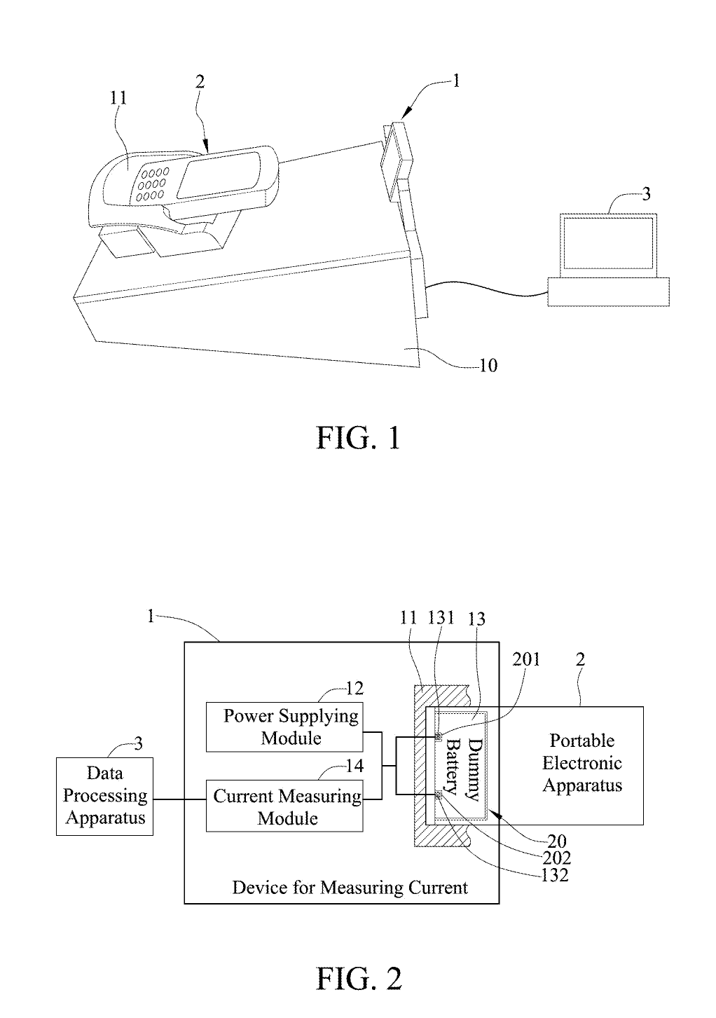

Referring to FIGS. 1 and 2 together, a schematic diagram depicting the appearance of a device for measuring current according to an embodiment of the present invention is shown in FIG. 1, and a block diagram depicting basic functional architecture of the device for measuring current according to an embodiment of the present invention is shown in FIG. 2. As shown, the device for measuring current 1 includes a body 10, a container 11, a power supplying module 12, a dummy battery 13, and a current measuring module 14.

It should be noted that this device for measuring current 1 of the present invention is applicable to a testing procedure of a portable electronic apparatus 2, such as a palm computer or a smart phone. That is, any portable electronic apparatus with a built-in battery (not shown) is applicable, such as a current method of supplying power to a mobile phone. The portable electronic apparatus 2 has a battery compartment 20 for receiving the battery, so that the dummy battery 13 can be installed therein during testing to supply power to the portable electronic apparatus 2.

The working principle behind the device for measuring current 1 of the present invention is to retrieve a current consumption of the built-in battery when the portable electronic apparatus 2 is performing a specific function and use it as the basis for current measurement. The principle and actual implementations of the device for measuring current 1 of the present invention are described in more details below.

It should be noted that the device for measuring current 1 of the present invention needs to connect to a data processing apparatus 3 loaded with a current value comparison program for quality testing of the portable electronic apparatus 2. The data processing apparatus 3 is for example a computer. More particularly, the current value comparison program is preset with a current range. This current range corresponds to a specific function of the portable electronic apparatus 2, so that a current value measure by the current measuring module 14 is compared with the preset current range. That is, if the current value falls within the preset current range, then the quality of the portable electronic apparatus 2 is considered as good; else if the current value falls outside the preset current range, then the quality of the portable electronic apparatus 2 is considered as no good, this will be described in more details later.

The container 11 is provided on a surface of the body 10 for receiving the portable electronic apparatus 2 to be tested. The shape and volume of this container 11 is adjusted flexibly according to the portable electronic apparatus 2. For example, it may have a ‘U″ shape to facilitate insertion of the portable electronic apparatus 2 via its top opening by the testing personnel.

The power supplying module 12 is used for generating a low-voltage current. More particularly, the power supplying module 12 is provided in the body 10 to change an input source such as AC power supply to various appropriate power supplies providing different power and/or different modes required by the testing personnel. For example, the low-voltage current generated by the power supplying module 12 is a low-voltage DC current.

The dummy battery 13 has an appearance similar to a battery for providing power for operating the portable electronic apparatus 2. That is, the shape of the dummy 13 is like the battery of the portable electronic apparatus 2 so it can be fitted in the battery compartment 20. The dummy battery 13 electrically connects the power supplying module 12 and the portable electronic apparatus 2 for providing the low-voltage current generated by the power supplying module 12 to the battery compartment 20, forming a power supply loop to the portable electronic apparatus 2. More particularly, the battery compartment 20 of the portable electronic apparatus 2 has a first positive terminal 201 and a first negative terminal 202. The first positive terminal 201 and first negative terminal 202 corresponds to the power output terminals of said battery for providing power for operating the portable electronic apparatus 2, respectively. The dummy battery 13 has a second positive terminal 131 and a second negative terminal 132 corresponding to the first positive terminal 201 and first negative terminal 202 of the battery compartment 20 and similar to the power output terminals, respectively. Accordingly, the second positive terminal 131 and second negative terminal 132 of the dummy battery 13 are connected by physical contact to the first positive terminal 201 and first negative terminal 202 of the battery compartment 20, and the second positive terminal 131 and second negative terminal 132 of the dummy battery 13 are connected through wires (not shown) to the power supplying module 12.

The current measuring module 14 is also contained in the body 10. The current measuring module 14 electrically connects to the power supply loop so as to measure a current value of the loop when the portable electronic apparatus 2 is performing a specific function, and transmit the measured current value to the data processing apparatus 3 for comparison. More particularly, the specific function performed by the portable electronic apparatus 2 can be a call, an incoming call/message notice, wireless network searching, wireless transmission of files, video playing, or message/email inputting and the like.

When the testing personnel carries out a current test procedure on the portable electronic apparatus 2, the device for measuring current 1 needs to be connected to the data processing apparatus 3 loaded with the current value comparison program, and then the dummy 13 is inserted into the battery compartment 20 of the portable electronic apparatus 2, and then the device for measuring current 1 is turned on. As a result, the power supplying module 12 generates a low-voltage current, which is provided to the portable electronic apparatus 2 via the dummy battery 13, thus forming a power supply loop to the portable electronic apparatus 2.

As mentioned above, the current measuring module 14 measures a DC current value of the power supply loop while the portable electronic apparatus 2 is performing a specific function, and then transmits this measured current value to the data processing apparatus 3 for comparing it with a preset current range corresponding to the specific function of the portable electronic apparatus 2. For example, the ideal current range of current consumed while the portable electronic apparatus 2 is performing wireless network searching is from 700 mA to 800 mA. In actual testing, the DC current value measured by the current measuring module 14 is 750 mA, which falls within the preset current range of 700 mA to 800 mA, and thus a result that the quality of the portable electronic apparatus 2 is good can be inferred.

On the other hand, in actual testing, the DC current value measured by the current measuring module 14 is 850 mA, which falls outside the preset current range of 700 mA to 800 mA, and thus a result that the quality of the portable electronic apparatus 2 is no good can be inferred.

Needless to say, during the above test, the results regardless of whether the quality of the portable electronic apparatus 2 is good or no good can be displayed on a display interface of the data processing apparatus 3, and the testing personnel can act accordingly.

In summary, compared to the prior art, the present invention allows the testing personnel to perform a current measuring procedure on the portable electronic apparatus through simple and convenient steps, which eliminates the need for manual operation, determination, and connection of connectors between various components. Thus, a more accurate test result can be obtained. Further, the overall yield of the portable electronic apparatus 2 is efficiently improved, thus reducing the production cost of the manufacturer is reduced.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A device for measuring current connected to a data processing apparatus loaded with a current value comparison program for performing a quality test on a portable electronic apparatus with a battery, the portable electronic apparatus having a battery compartment for receiving the battery, the device for measuring current comprising:
a power supplying module for generating a low-voltage current;
a dummy battery with a shape of the battery for inserting into the battery compartment, the dummy battery electrically connected to the power supplying module and the portable electronic apparatus so as to provide the low-voltage current generated by the power supply module to the portable electronic apparatus and to form a power supply loop to the portable electronic apparatus; and
a current measuring module electrically connected to the power supply loop for measuring a current value of the power supply loop when the portable electronic apparatus is performing a specific function and transmitting the measured current value to the data processing apparatus for comparison.

2. The device for measuring current of claim 1, further comprising a body including a container on a surface thereof for receiving the portable electronic apparatus.

3. The device for measuring current of claim 1, wherein the battery compartment includes a first positive terminal and a first negative terminal corresponding to power output terminals of the battery.

4. The device for measuring current of claim 3, wherein the dummy battery includes a second positive terminal and a second negative terminal corresponding to the first positive terminal and the first negative terminal of the battery compartment and with shapes of the power output terminals of the battery.

5. The device for measuring current of claim 4, wherein the second positive terminal and the second negative terminal of the dummy battery are connected to the first positive terminal and the first negative terminal of the battery compartment by physical contact, respectively, and connected to the power supplying module via wires.

6. The device for measuring current of claim 1, wherein the specific function performed by the portable electronic apparatus is a call, an incoming call/message notice, wireless network searching, wireless transmission of files, video playing, or message/email inputting.

7. The device for measuring current of claim 6, wherein a current range is preset in the current value comparison program, the current range being set correspondingly to the specific function of the portable electronic apparatus, and for comparison with the current value measured by the current measuring module.

8. The device for measuring current of claim 7, wherein when the current value falls within the preset current range, quality of the portable electronic apparatus is considered as good.

9. The device for measuring current of claim 7, wherein when the current value falls outside the preset current range, quality of the portable electronic apparatus is considered as no good.
